(19) United States
(12) Patent Application Publication
(10) Pub. No.: US 2026/0353692 A1
(43) Pub. Date: Nov. 5, 2026

(54) METHOD FOR FABRICATING A JFET USING A PROGRESSION OF SELF-ALIGNED PROCESSING TECHNIQUES

(71) Applicant: SEMICONDUCTOR COMPONENTS INDUSTRIES, LLC, Scottsdale, AZ (US)

(72) Inventor: Alexander Viktorovich BOLOTNIKOV, Niskayuna, NY (US)

(73) Assignee: SEMICONDUCTOR COMPONENTS INDUSTRIES, LLC, Scottsdale, AZ (US)

(21) Appl. No.: 19/196,324

(22) Filed: May 1, 2025

(51) Int. Cl. H10D 30/01; H10D 30/83; H10D 62/17; H10D 62/832

(52) U.S. Cl. CPC H10D 30/051; H10D 30/832; H10D 62/235; H10D 62/8325

(57) ABSTRACT

A method for fabricating a junction field-effect transistor (JFET) is disclosed. The method includes forming a source region adjacent to a surface of a semiconductor substrate, forming a spacer with a spacer material above the surface of the semiconductor substrate, and forming a gate region, wherein the gate region is masked by the spacer to define a boundary of a channel region extending vertically from the source region toward a drift region. The method further includes increasing a spacer width of the spacer, etching through the source region and to the gate region using the spacer as a mask, and forming a gate contact region in the gate region.

### TECHNICAL FIELD

The disclosure relates generally to junction field-effect transistors (JFETs), and particularly to methods for fabricating JFETs utilizing self-aligned processing techniques.

### BACKGROUND

Power electronics promote conversion and distribution of electrical power from a power source to electronics and electrical machines. A power conversion circuit is often at the heart of each electronic power system and may be configured to convert electrical power from a raw unregulated form and quantity as produced by the power source to an appropriate regulated form and quantity as needed by machines, motors, and/or other electronic equipment.

JFETs may be used in power electronics, such as switching power converters and inverters. In some applications, a JFET may be formed as a discrete component included in an integrated circuit package. A key parameter for a JFET used in power electronics applications may be the on-state resistance (RON) of the JFET. For example, a lower on-state resistance may provide for a smaller voltage drop at a given current load. Thus, a lower on-state resistance may provide for less conduction losses in the system in which the JFET is implemented.

The inventor of embodiments of the present disclosure has recognized that increasing the number of active cells in a JFET may reduce on-state resistance, but typically at the cost of a larger chip area and cost. The inventor of embodiments of the present disclosure has also recognized that typical techniques for improving the area utilization of JFETs have been limited by the minimum feature sizes (for example, for lines, spaces, overlays, among others) of the photolithography processes used to manufacture JFETs. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a cross-section view of a vertical channel JFET in accordance with embodiments of the present disclosure.

FIGS. 2A-2P illustrate a series of cross-section views during fabrication of a JFET in accordance with embodiments of the present disclosure.

FIG. 3 illustrates an example method for fabricating a JFET in accordance with embodiments of the present disclosure.

FIG. 4 illustrates an example method for fabricating a JFET in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to.” Also, the term “couple” or “coupled” is intended to mean either an indirect or direct connection. Thus, if a first device couples to, or is coupled to, a second device, that connection between the first device and the second device may be through a direct connection or through an indirect connection via other devices and connections.

Further, although the terms “first,” “second,” and so forth may be used herein to describe various elements, these elements should not be limited by these terms. Terms such as “first” and “second” may be used merely to distinguish one element from another. For example, a first element could be termed a second element, and, similarly, a second element could be termed a first element, without departing from the scope of the present disclosure. Further, the identification of a “first” element, does not necessarily require the presence of a “second” element. As used herein, the term “and/or” includes any and all combinations of one or more of the associated listed items.

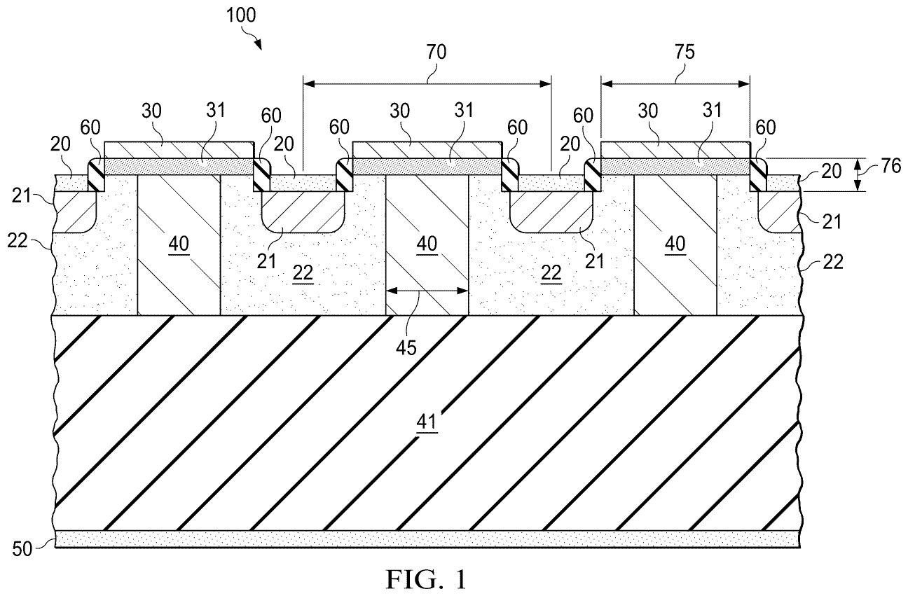

FIG. 1 illustrates a cross-section view of JFET 100 in accordance with embodiments of the present disclosure. JFET 100 may be a planar vertical JFET. For example, as shown in FIG. 1, JFET 100 may include channel region 40 extending vertically between source region 31 and drift region 41. Source region 31 may be disposed in a mesa between two dielectric spacers 60. Further, source region 31 may be coupled to source contact 30 on a first surface of the semiconductor substrate. JFET 100 may also include gate region 22 disposed on opposing sides of channel region 40. As shown in FIG. 1, gate region 22 may include different portions on opposing sides of channel region. For the purposes of the present disclosure, the different portions of gate region 22 may be referred to collectively as the gate region 22. JFET 100 may also include a gate contact region 21 disposed within gate region 22 and coupled to gate contact 20. Further, JFET 100 may include drift region 41 coupled to drain contact 50 on a second surface of the semiconductor substrate opposing the first surface on which source contact 30 is formed.

In some embodiments, each of source region 31, channel region 40, and drift region 41 may be formed with a first conductivity type, while gate contact region 21 and gate region 22 may be formed with a second conductivity type opposite of first conductivity type. For example, in embodiments where JFET 100 is an n-channel JFET, source region 31, channel region 40, and drift region 41 are n-type regions, while gate contact region 21 and gate region 22 are p-type regions. And in embodiments where JFET 100 is a p-channel JFET, source region 31, channel region 40, and drift region 41 are p-type regions, while gate contact region 21 and gate region 22 are n-type regions.

As described in further detail below, channel region 40 may be formed in the upper portion of drift region 41. In some embodiments, channel region 40 may have the same doping type and doping concentration as drift region 41. In other embodiments, channel region 40 may have the same doping type but a different doping concentration than drift region 41. For example, channel region 40 may be more heavily doped than drift region 41. Further, although the depth of channel region 40 is illustrated in FIG. 1 as approximately equal to the depth of gate region 22, the depth of channel region 40 may be greater or lesser than the depth of gate region 22.

As shown in FIG. 1, channel region 40 may extend vertically between portions of gate regions 22. Accordingly, a voltage applied to gate contact region 21 and gate region 22 relative to the source contact 30 and source region 31 may serve to modulate the conductive properties of channel region 40, thus varying the conductivity of JFET 100 from drain to source. Although not shown in FIG. 1, JFET 100 may in some embodiments include an additional current-spreading layer under channel region 40 and gate region 22, and above drift region 41. Such an additional current-spreading layer may be of the same first conductivity type as channel region 40 and drift region 41, and may have any suitable doping level to spread the flow carriers across upper portion of drift region 41.

In some embodiments, JFET 100 may be a silicon carbide JFET. For example, in some embodiments, each of gate contact region 21, gate region 22, source region 31, channel region 40, and drift region 41 may be formed in an epitaxially grown layer of silicon carbide. In other embodiments, a lower portion of drift region 41 may also include a low-resistivity substrate region on which the aforementioned epitaxially grown semiconductor material was formed. JFET 100 may also be formed in any other suitable semiconductor material, including but not limited to silicon (Si), gallium nitride (GaN), diamond, gallium oxide (Ga₂O₃).

Gate contact 20 and source contact 30 may be formed with a metal or a silicide, including for example a nickel-silicide, or any other silicide, metal, metal alloy, or combination thereof, suitable for making an ohmic contact with the respective gate contact region 21 and source region 31 beneath gate contact 20 and source contact 30. Further, drain contact 50 may be made of a metal or a silicide, including for example a nickel-silicide, or any other silicide, metal, metal alloy, or combination thereof, suitable for making an ohmic contact with drift region 41. In some embodiments, gate contact 20, source contact 30, and/or drain contact 50 may include the same metal, silicide, or combination thereof, as each other. In other embodiments, gate contact 20 and source contact 30, may be formed with a different metal, silicide, or combination thereof, compared to drain contact 50. Although not shown in FIG. 1, JFET 100 may include further layers of metal or metal alloys patterned within interlayer dielectrics to respectively couple source contact 30 to the source terminal of JFET 100, gate contact 20 to gate terminal of JFET 100, and drain contact 50 to the drain terminal of JFET 100.

JFET 100 may include multiple JFET cells. The multiple JFET cells may be coupled in parallel to each other and may extend in a linear manner into the page relative to the cross-section view of FIG. 1, to form a striped layout pattern. For illustration purposes, FIG. 1 shows a cross-section view of three cells of JFET 100. However, JFET 100 may include any suitable number of cells laid out in parallel to each other. For example, JFET 100 may include 10, 100, 1000, 10000, or more JFET cells laid out in parallel to each other. A larger number of JFET cells may increase the number of channel regions 40 through which current may flow, thereby reducing the on-state resistance of JFET 100.

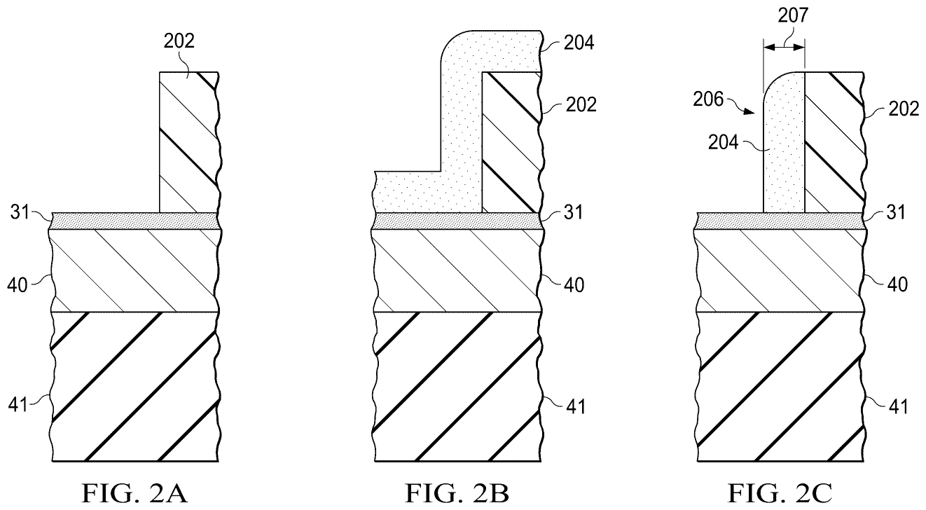

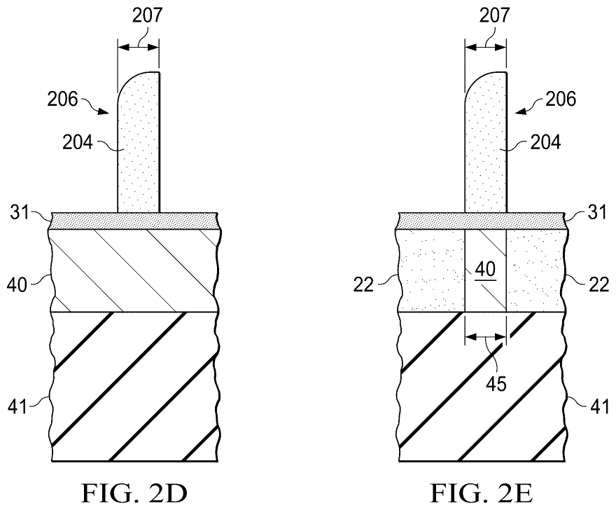

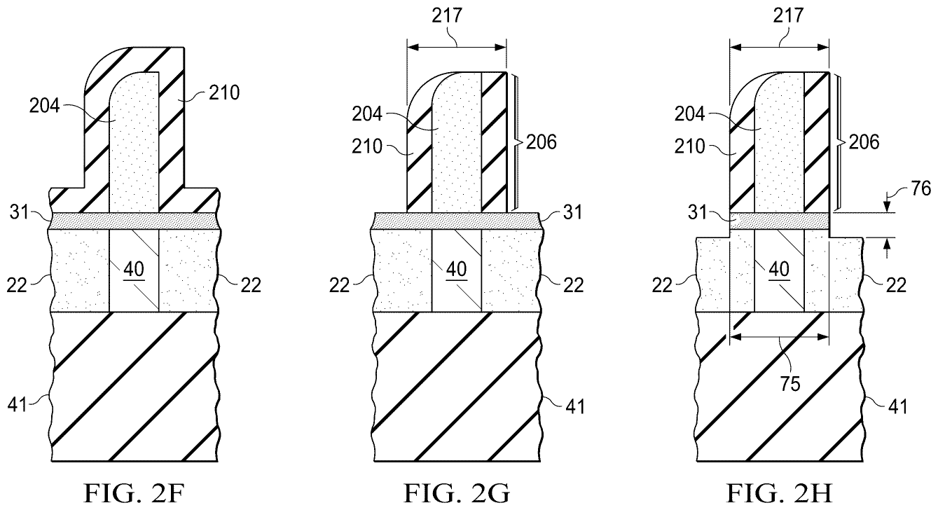

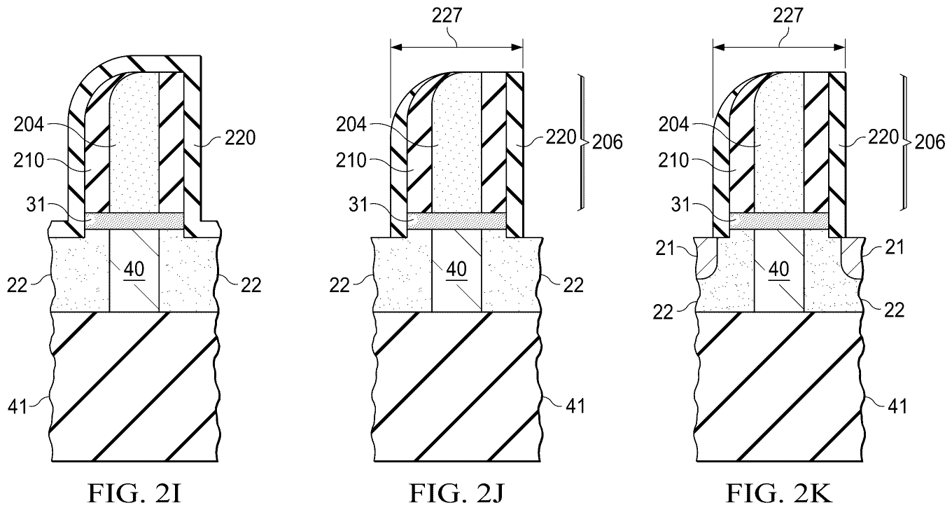

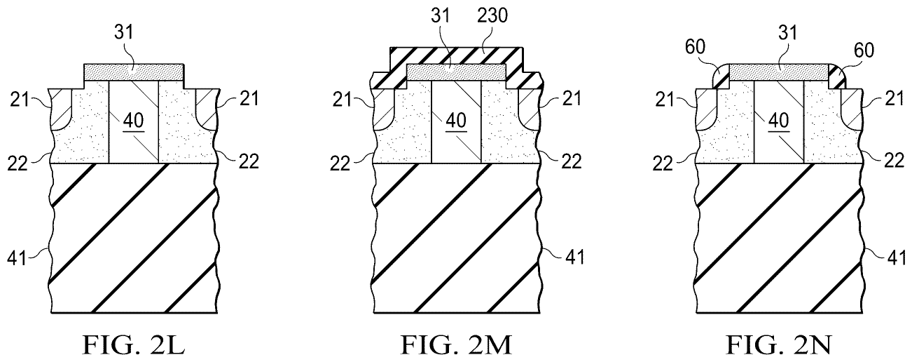

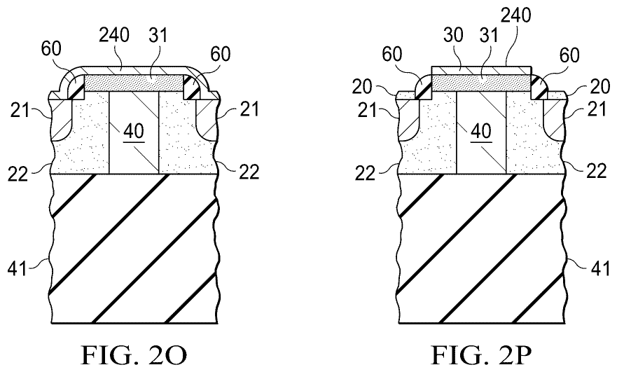

As described in detail below with reference to FIGS. 2A-2P, FIG. 3, and FIG. 4, JFET 100 may formed by using a series of self-aligning techniques, thereby providing dimensions that are more tightly spaced as compared to the dimensions achievable by the use of lithography during the semiconductor fabrication process. In some embodiments, and due to the self-alignment techniques described herein, JFET 100 may have a channel width 45 that is 1 μm or less. For example, channel region 40 may have a channel width 45 in a channel-width range of 0.2 μm to 1 μm. In some examples, channel region 40 may have a channel width 45 in a channel-width range of 0.2 μm to 0.5 μm. Further, in some embodiments, and due to the self-alignment techniques described herein, JFET 100 may have a cell pitch 70 that is 2 μm or less. For example, JFET 100 may have a cell pitch that is in a range of 1 μm to 2 μm. By providing a cell pitch 70 that is, for example, 2 μm or less, JFET 100 may include a larger number of cells for a given semiconductor area, thereby providing a lower on-state resistance for JFET 100 for a given chip area.

Further, as described in further detail below with reference to FIG. 2H, the semiconductor substrate may be etched to form a mesa within which source region 31 is disposed. Due to the self-aligning techniques described herein, JFET 100 may have a mesa-width 75 that is 1 μm or less. For example, JFET 100 may have a mesa-width 75 in a width range of 0.5 μm to 1 μm. Further, in some embodiments, JFET 100 may have a mesa-depth 76 that is 0.3 μm or less. For example, JFET 100 may have a mesa-depth 76 in a depth range of 0.1 μm to 0.3 μm.

Further, although not shown in FIG. 1, JFET 100 may also include a termination region surrounding a plurality of JFET cells forming JFET 100. For example, the termination region may be located on the outer edges of the active region of JFET 100. The termination region may define an outer perimeter of the active area in which a plurality of JFET cells is formed. In some embodiments, the termination region may include one or more doped regions, formed for example by diffusion or implantation, and/or one or more trench structures, to reduce gradients of the electric field at geometrical sharp points associated with operation of the JFET device at high voltages. Thus, the termination region may help maintain the breakdown voltage (BV) of the JFET cells close to a maximum BV as limited by material properties. For example, the termination region may prevent breakdown from occurring below a blocking entitlement of the plurality of JFET cells, for example, by terminating or gradually reducing high electric fields at device periphery during off-state operation of JFET 100. The termination region or portions of such may have a second conductivity type opposite of the first conductivity type. For example, in embodiments where source region 31, channel region 40, and drift region 41 are n-type regions, the termination region may be a p-type region. And in embodiments where source region 31, channel region 40, and drift region 41 are p-type regions, the termination region may be an n-type region.

FIGS. 2A-2P illustrate a series of cross-section views during fabrication of JFET 100 in accordance with embodiments of the present disclosure.

As shown in FIG. 2A, a semiconductor substrate may be provided including drift region 41. In some embodiments, the upper portion of drift region 41 that forms channel region 40 may be formed by an epitaxial growth on the substrate that forms the lower portion of drift region 41. In such embodiments, channel region 40 may be doped in-situ during the epitaxial growth, or by later doping after the formation of channel region 40.

In some embodiments, further doping of the same conductivity type as drift region 41 and channel region 40 may be added at the upper surface of the semiconductor substrate to form source region 31 adjacent to the upper surface of the semiconductor substrate. Source region 31 may have a higher doping concentration than channel region 40.

As shown in FIG. 2A, patterned mask 202 may be formed over the semiconductor substrate. For example, patterned mask 202 may be formed on the upper surface of the semiconductor substrate above source region 31. Patterned mask 202 may include a mask material such as a polysilicon, an oxynitride, or an oxide such as silicon dioxide. In some embodiments, patterned mask 202 may be formed using lithography.

Moving next to FIGS. 2B and 2C, spacer 206 may be formed above the upper surface of the semiconductor substrate. For example, as shown in FIG. 2B, a spacer material 204 may be conformally deposited over patterned mask 202 and the semiconductor substrate. The spacer material 204 may include any suitable material to serve as a mask for later processing steps. For example, spacer material 204 may include one or more of a polysilicon, an oxynitride, or an oxide such as silicon dioxide. In some embodiments, spacer material 204 may be a different material than patterned mask 202 such that patterned mask 202 and spacer material 204 may be separately targeted by later etching processes.

As shown in FIG. 2C, an isotropic etch (also referred to as a directional etch) may be applied to remove portions of spacer material 204. The isotropic etch may be implemented by a chemical etch, a plasma etch, a combination of a chemical and plasma etch, or any other etching process suitable to target spacer material 204. For example, the isotropic etch may be configured to vertically target spacer material 204 to remove the upper and lower portions of spacer material 204 extending horizontally and parallel to the surface of the semiconductor substrate. The isotropic etch of spacer material 204 may leave a spacer 206 that is vertically oriented relative to the surface of the semiconductor substrate. As shown in FIG. 2C, spacer 206 may have a first spacer width 207.

Moving of FIG. 2D, another etch may be applied to remove patterned mask 202. For example, the etch may be implemented by a chemical etch, a plasma etch, a combination of a chemical and plasma etch, or any other etching process suitable to target and remove patterned mask 202. In some embodiments, the etch may be configured to have an etch rate for patterned mask 202 that is for example 5, 10, 20, or more times faster than the etch rate for spacer 206. Accordingly, the etch shown by the transition from FIG. 2C to FIG. 2D may remove patterned mask 202 while leaving spacer 206 largely intact with the first spacer width 207.

Moving next to FIG. 2E, gate region 22 may be formed in the semiconductor substrate. Gate region 22 may be formed by doping portions of the semiconductor substrate with an opposite conductivity type relative to drift region 41, channel region 40, and source region 31. The doping for gate region 22 may be applied by diffusion, ion implantation, or any other suitable doping technique. As shown in FIG. 2E, the formation of gate region 22 may be masked by spacer 206 to define a boundary of channel region 40, whereby channel region 40 extends vertically from source region 31 toward drift region 41. For example, in embodiments such as shown in FIG. 2E without a separate current-spreading layer between channel region 40 and drift region 41, channel region 40 may extend vertically from source region 31 all the way to drift region 41.

As shown in FIG. 2E, channel region 40 may have a channel width 45 based on the first spacer width 207 of spacer 206. The channel width 45 of channel region 40 may thus be 1 μm or less. For example, channel region 40 may have a channel width 45 in a channel-width range of 0.2 μm to 1 μm. In some examples, channel region 40 may have a channel width 45 in a channel-width range of 0.2 μm to 0.5 μm.

Further, respective portions of gate region 22 may be formed at a distance from each other to provide a cell pitch that is 2 μm or less. For example, respective portions of gate region 22 may be formed at a distance from each other to provide a cell pitch in the range of 1 μm to 2 μm. By providing a cell pitch 70 (shown in FIG. 1) that is, for example, 2 μm or less, the JFET may include a larger number of cells for a given semiconductor area, thereby providing a lower on-state resistance for a given chip area.

Moving next to FIGS. 2F and 2G, the spacer width of spacer 206 may be increased. For example, the spacer width of spacer 206 may be increased or widened from a first spacer width 207 to a second spacer width 217 that is greater than the first spacer width 207. As shown in FIG. 2F, a second spacer layer 210 may be conformally deposited over spacer material 204 and the semiconductor substrate. The second spacer layer 210 may include any suitable material to serve as a mask for later processing steps. For example, second spacer layer 210 may include one or more of a polysilicon, an oxynitride, or an oxide such as silicon dioxide. In some embodiments, second spacer layer 210 may be formed with the same material or combination of materials as spacer material 204.

As shown in FIG. 2G, an isotropic etch may be applied to remove portions of second spacer layer 210. The isotropic etch may be implemented by a chemical etch, a plasma etch, a combination of a chemical and plasma etch, or any other etching process suitable to target second spacer layer 210. For example, the isotropic etch may be configured to vertically target the material of second spacer layer 210 to remove the upper and lower portions of second spacer layer 210 extending horizontally and parallel to the surface of the semiconductor substrate. The isotropic etch of second spacer layer 210 may leave a portion of second spacer layer 210 on the sidewalls of spacer material 204, thereby increasing the spacer width of spacer 206 from a first spacer width 207 (shown in FIGS. 2D and 2E) to a second spacer width 217 (shown in FIG. 2G).

Moving next to FIG. 2H, the semiconductor substrate may be etched using spacer 206 as a mask. For example, etch may be implemented by a chemical etch, a plasma etch, a combination of a chemical and plasma etch, or any other suitable etching process to etch into the semiconductor substrate. For example, as shown in FIG. 2H, a trench may be formed by etching through source region 31 and to gate region 22 using spacer 206 (the second spacer width 217 of spacer 206) as a mask. In some embodiments, etching through source region 31 to gate region 22 using spacer 206 as a mask may create a mesa (within which remaining portions of source region 31 are disposed) having a mesa-depth 76 that is 0.3 μm or less. For example, the mesa may have a mesa-depth 76 in a depth range of 0.1 μm to 0.3 μm. The mesa may further have a mesa-width 75 that is 1 μm or less. For example, the mesa may have a mesa-width 75 in a width range of 0.5 μm to 1 μm.

Moving next to FIGS. 2I and 2J, the spacer width of spacer 206 may be further increased or widened. For example, the spacer width of spacer 206 may be increased or widened from a second spacer width 217 to a third spacer width 227 that is greater than the second spacer width 217. As shown in FIG. 2I, an additional spacer layer 220 may be conformally deposited over spacer material 204, second spacer layer 210, and the semiconductor substrate. The additional spacer layer 220 may include any suitable material to serve as a mask for later processing steps. For example, additional spacer layer 220 may include one or more of a polysilicon, an oxynitride, or an oxide such as silicon dioxide. In some embodiments, additional spacer layer 220 may be formed with the same material or combination of materials as spacer material 204 and/or second spacer layer 210.

As shown in FIG. 2J, an isotropic etch may be applied to remove portions of additional spacer layer 220. The isotropic etch may be implemented by a chemical etch, a plasma etch, a combination of a chemical and plasma etch, or any other etching process suitable to target additional spacer layer 220. For example, the isotropic etch may be configured to vertically target the material of additional spacer layer 220 to remove the upper and lower portions of additional spacer layer 220 extending horizontally and parallel to the surface of the semiconductor substrate. The isotropic etch of additional spacer layer 220 may leave a portion of additional spacer layer 220 on the sidewalls of second spacer layer 210, thereby increasing the spacer width of spacer 206 from a second spacer width 217 (shown in FIGS. 2G and 2H) to a third spacer width 227 (shown in FIG. 2J).

Moving next to FIG. 2K, gate contact region 21 may be formed in gate region 22 using spacer 206 as a mask. Gate contact region 21 may be formed by doping portions of the gate region 22 with a higher doping concentration of the same conductivity type as gate region 22. The doping for gate contact region 21 may be applied by diffusion, ion implantation, or any other suitable doping technique. In some embodiments, the higher doping concentration of gate contact region 21 may help facilitate the formation of a low-resistance gate contact 20 coupled to gate contact region 21 as described in further detail below with reference to FIGS. 2O and 2P.

As shown in FIG. 2K, the formation of gate contact region 21 may be masked by spacer 206. The additional spacer layer 220 of spacer 206 may shield source region 31 from the doping used to form gate contact region 21. In some embodiments, the doping concentration (of the first conductivity type) of source region 31 may be significantly higher than the doping concentration (of the second conductivity type) used to form gate contact region 21. In such embodiments, the higher doping concentration of the first conductivity type for source region 31 may predominate even when exposed to the doping of the second conductivity type for gate contact region 21. Thus, in such embodiments, the addition of additional spacer layer 220 by the processing steps illustrated by FIGS. 2I and 2J may optionally be omitted.

Moving next to FIG. 2L, spacer 206 may be removed. For example, an etch targeting spacer material 204, second spacer layer 210, and/or additional spacer layer 220 may be applied to remove spacer 206 from the upper surface of the semiconductor substrate. After spacer 206 has been removed, other features of the device not shown in FIG. 2L may be added. For example, a termination region (not shown in FIG. 2L) may be formed around an outer perimeter of the active area in which the plurality of JFET cells is formed. In some embodiments, the termination region may include one or more doped regions, formed for example by diffusion or implantation, and/or one or more trench structures, to reduce gradients of the electric field at geometrical sharp points associated with operation of the JFET device at high voltages. Further, a high-temperature activation (HTA) and/or a driven-in diffusion may be performed to activate the implanted impurities, including the doping applied to form the termination region described directly above, and/or the implanted impurities applied to form gate region 22 and gate contact region 21 as described above with reference to FIGS. 2E and 2K.

Moving next to FIGS. 2M and 2N, dielectric spacers 60 may be formed on the sidewalls of source region 31. As shown in FIG. 2M, a dielectric layer 230 may be conformally deposited over the semiconductor substrate, including over gate contact region 21, gate region 22, and the mesa in which source region 31 is disposed. The dielectric layer 230 may include any suitable dielectric material to electrically insulate source region 31 from later added metal routing that couples gate contact region 21 to a gate terminal of the JFET 100. For example, dielectric layer 230 may include silicon dioxide or any other suitable dielectric material.

As shown in FIG. 2N, an isotropic etch may be applied to remove portions of dielectric layer 230. The isotropic etch may be implemented by a chemical etch, a plasma etch, a combination of a chemical and plasma etch, or any other etching process suitable to target dielectric layer 230. For example, the isotropic etch may be configured to vertically target the material of dielectric layer 230 to remove the upper and lower portions of dielectric layer 230 extending horizontally and parallel to the surface of the semiconductor substrate. The isotropic etch of dielectric layer 230 may leave vertically oriented portions of dielectric layer 230 to form dielectric spacers 60 on the sidewalls of source region 31.

Moving next to FIG. 2O, a metal layer 240 may be conformally deposited on over the semiconductor substrate, including over source region 31, dielectric spacers 60, and gate contact region 21. Metal layer 240 may be formed with any suitable metal or metal alloy. As one example, metal layer 240 may include nickel (N) or an alloy thereof. After depositing metal layer 240, an anneal may be performed. For example, a low-temperature rapid thermal anneal (RTA) may be performed to cause portions of metal layer 240 to react with underlying areas of source region 31 and gate contact region 21. The reaction of metal with underlying semiconductor regions may form areas of silicide, for example a nickel silicide.

Moving next to FIG. 2P, the non-reacted portions of metal layer 240, including the non-reacted portions of metal layer 240 above dielectric spacers 60, may be removed. The reacted portions of metal layer 240 may remain. For example, as shown in FIG. 2P, gate contact 20 and source contact 30 may be formed by the remaining areas of silicide (for example, nickel silicide) where metal layer 240 reacted with underlying areas of source region 31 and gate contact region 21. A second rapid thermal anneal (RTA) may then be performed, at a higher temperature than the first RTA described above with reference to FIG. 2O, to further anneal gate contact 20 and source contact 30, thereby further reducing the contact resistance of gate contact 20 and source contact 30.

After gate contact 20 and source contact 30 are formed, further processing steps may be utilized to couple gate region 22, source region 31, and drift region 41 to the respective gate, source, and drain terminals of the JFET device. For example, a silicide may be formed on the backside of the semiconductor substrate to form a drain contact, as illustrated by drain contact 50 in FIG. 1. Further, one or more metal layers (separated by one or more interlayer dielectrics and/or passivation layers) may be patterned and formed to provide routing from gate contact 20 to a gate pad on a pad-metal layer, to provide routing from source contact 30 to a source pad on the pad-metal layer.

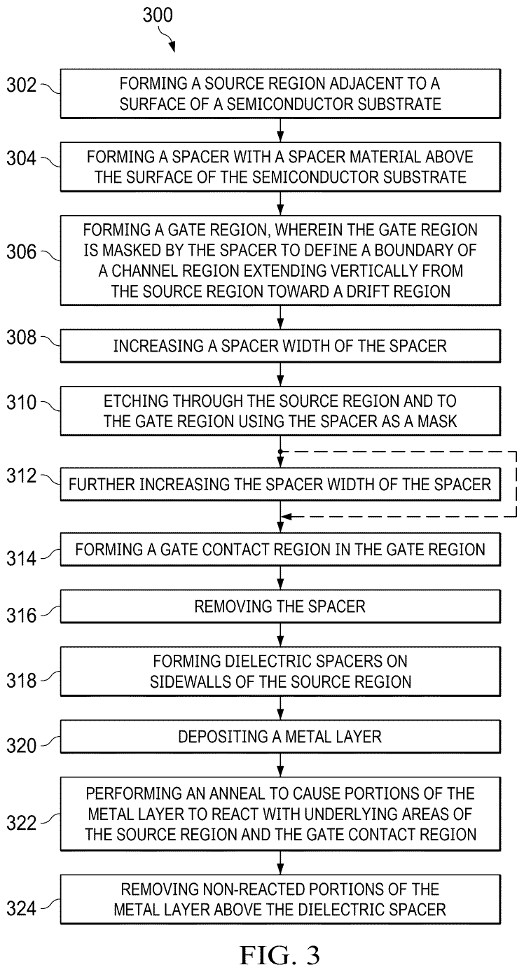

FIG. 3 illustrates a method 300 for fabricating a JFET device in accordance with embodiments of the present disclosure. In some embodiments, the steps of method 300 may be performed with fewer or more steps than shown in FIG. 3. For the sake of simplicity, additional fabrication steps such as the formation of the source, gate, and termination regions, as well as the back-side metallization to form drain contacts, are omitted from the steps of method 300. Moreover, in some embodiments, certain steps of method 300 may be omitted, repeated, performed in parallel, performed in a different order than shown in FIG. 3, or performed recursively. As one example, step 312 may be omitted in some embodiments.

Step 302 may include forming a source region adjacent to a surface of a semiconductor substrate. For example, as described above with reference to FIG. 2A, doping of a heavier concentration and the same conductivity type as drift region 41 and channel region 40 may be added at the upper surface of the semiconductor substrate to form source region 31 adjacent to the upper surface of the semiconductor substrate.

Step 304 may include forming a spacer with a spacer material above the surface of the semiconductor substrate. For example, as described above with reference to FIGS. 2B-2D, spacer 206 may be formed with spacer material 204 on the upper surface of the semiconductor substrate. In some embodiments, forming spacer 206 above the surface of the semiconductor substrate may include forming a patterned mask 202 over the semiconductor substrate, depositing spacer material 204 over patterned mask 202 and the semiconductor substrate, performing an isotropic etch targeting spacer material 204, and removing the patterned mask 202.

Step 306 may include forming a gate region, wherein the gate region is masked by the spacer to define a boundary of a channel region extending vertically from the source region toward a drift region. For example, as described above with reference to FIG. 2E, gate region 22 may be formed by doping portions of the semiconductor substrate with an opposite conductivity type relative to drift region 41, channel region 40, and source region 31. As shown in FIG. 2E, the formation of gate region 22 may be masked by spacer 206 to define a boundary of channel region 40, whereby channel region 40 extends vertically from source region 31 toward drift region 41.

Step 308 may include increasing a spacer width of the spacer. In some embodiments, increasing the spacer width of the spacer may include depositing a second spacer layer over the spacer material and the semiconductor substrate, and performing an isotropic etch targeting the second spacer layer. For example, as described above with reference to FIGS. 2F and 2G, the spacer width of spacer 206 may be increased or widened from a first spacer width 207 to a second spacer width 217 that is greater than the first spacer width 207. As shown in FIG. 2F, a second spacer layer 210 may be conformally deposited over spacer material 204 and the semiconductor substrate. Then, as shown in FIG. 2G, an isotropic etch may be applied to remove portions of second spacer layer 210. The isotropic etch of second spacer layer 210 may leave a portion of second spacer layer 210 on the sidewalls of spacer material 204, thereby increasing the spacer width of spacer 206 from a first spacer width 207 (shown in FIGS. 2D and 2E) to a second spacer width 217 (shown in FIG. 2G).

Step 310 may include etching through the source region and to the gate region using the spacer as a mask. For example, as described above with reference to FIG. 2H, a trench may be formed by etching through source region 31 and to gate region 22 using spacer 206 (the second spacer width 217 of spacer 206) as a mask. In some embodiments, etching through source region 31 to gate region 22 using spacer 206 as a mask may create a mesa within which remaining portions of source region 31 are disposed.

Step 312 may include further increasing the spacer width prior to forming the gate contact region. In some embodiments, further increasing the spacer width may include depositing an additional spacer layer over the spacer and the semiconductor substrate, and performing an isotropic etch targeting the additional spacer layer. For example, as described above with reference to FIGS. 2I and 2J, the spacer width of spacer 206 may be increased or widened from a second spacer width 217 to a third spacer width 227, which is greater than the second spacer width 217. As shown in FIG. 2I, an additional spacer layer 220 may be conformally deposited over spacer material 204, second spacer layer 210, and the semiconductor substrate. Subsequently, as shown in FIG. 2J, an isotropic etch may be applied to remove portions of additional spacer layer 220. The isotropic etch of additional spacer layer 220 may leave a portion of additional spacer layer 220 on the sidewalls of second spacer layer 210, thereby increasing the spacer width of spacer 206 from a second spacer width 217 (shown in FIGS. 2G and 2H) to a third spacer width 227 (shown in FIG. 2J).

As shown in FIG. 2K, the additional spacer layer 220 of spacer 206 may shield source region 31 from the doping used to form gate contact region 21. In some embodiments, the doping concentration (of the first conductivity type) of source region 31 may be significantly higher than the doping concentration (of the second conductivity type) used to form gate contact region 21. In such embodiments, the higher doping concentration of the first conductivity type for source region 31 may predominate even when exposed to the doping of the second conductivity type for gate contact region 21. Thus, in such embodiments, the addition of additional spacer layer 220 by the processing steps illustrated by FIGS. 2I and 2J may optionally be omitted. For such embodiments, method 300 may optionally omit step 312 and may proceed directly from step 310 to step 314.

Step 314 may include forming a gate contact region in the gate region. For example, as described above with reference to FIG. 2K, gate contact region 21 may be formed in gate region 22 using spacer 206 as a mask. Gate contact region 21 may be formed by doping portions of the gate region 22 with a higher doping concentration of the same conductivity type as gate region 22. In some embodiments, the higher doping concentration of gate contact region 21 may help facilitate the formation in later processing steps of a low-resistance gate contact 20 coupled to gate contact region 21.

Step 316 may include removing the spacer. For example, as described above with reference to FIG. 2L, an etch targeting spacer material 204, second spacer layer 210, and/or additional spacer layer 220 may be applied to remove spacer 206 from the upper surface of the semiconductor substrate.

As also described above with reference to FIG. 2L, other features of the device, such as a termination region, may be added after removal of spacer 206. For example, a termination region may be formed around an outer perimeter of the active area in which the plurality of JFET cells is formed. In some embodiments, the termination region may include one or more doped regions, formed for example by diffusion or implantation, and/or one or more trench structures, to reduce gradients of the electric field at geometrical sharp points associated with operation of the JFET device at high voltages. A high-temperature activation (HTA) and/or a driven-in diffusion may be performed to activate the implanted impurities, including the doping applied to form the termination region described directly above, and/or the implanted impurities applied to form gate region 22 and gate contact region 21 as described above with reference to FIGS. 2E and 2K.

Step 318 may include forming dielectric spacers on sidewalls of the source region. For example, as described above with reference to FIGS. 2M and 2N, dielectric spacers 60 may be formed on the sidewalls of source region 31. As shown in FIG. 2M, a dielectric layer 230 may be conformally deposited over the semiconductor substrate, including over gate contact region 21, gate region 22, and the mesa in which source region 31 is disposed. Subsequently, as shown in FIG. 2N, an isotropic etch may be applied to remove the upper and lower portions of dielectric layer 230 extending horizontally and parallel to the surface of the semiconductor substrate. The isotropic etch of dielectric layer 230 may leave vertically oriented portions of dielectric layer 230 to form dielectric spacers 60 on the sidewalls of source region 31.

Step 320 may include depositing a metal layer. For example, as described above with reference to FIG. 2O, a metal layer 240 may be conformally deposited on over the semiconductor substrate, including over source region 31, dielectric spacers 60, and gate contact region 21. Metal layer 240 may be formed with any suitable metal or metal alloy, such as nickel (N) or an alloy thereof.

Step 322 may include performing an anneal to cause portions of the metal layer to react with underlying areas of the source region and the gate contact region. For example, as also described above with reference to FIG. 2O, a low-temperature rapid thermal anneal (RTA) may be performed to cause portions of metal layer 240 to react with underlying areas of source region 31 and gate contact region 21. The reaction of metal with underlying semiconductor regions may form areas of silicide, for example a nickel silicide.

Step 324 may include removing non-reacted portions of the metal layer above the dielectric spacer. For example, as described above with reference to FIG. 2P, the non-reacted portions of metal layer 240, including the non-reacted portions of metal layer 240 above dielectric spacers 60, may be removed. The reacted portions of metal layer 240 may remain. For example, as shown in FIG. 2P, gate contact 20 and source contact 30 may be formed by the remaining areas of silicide (for example, nickel silicide) where metal layer 240 reacted with underlying areas of source region 31 and gate contact region 21.

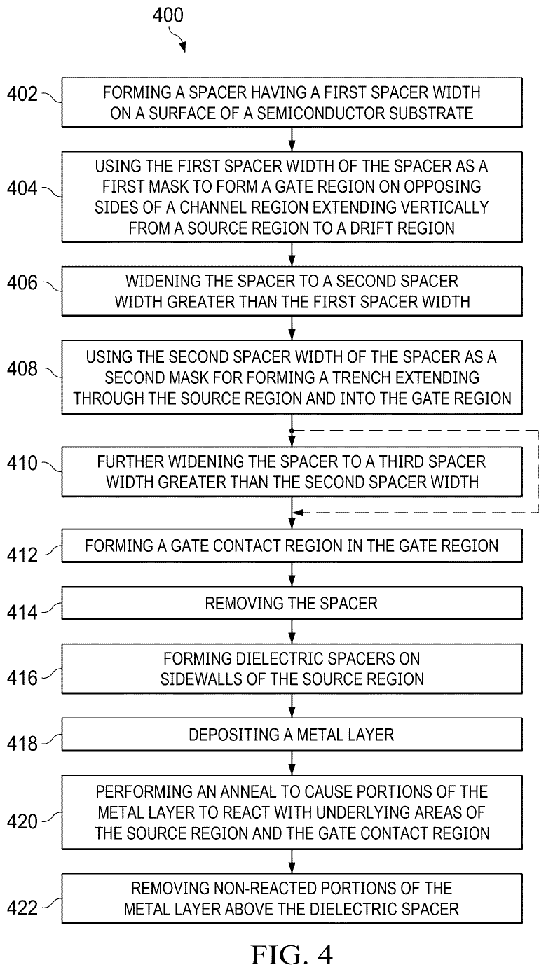

FIG. 4 illustrates a method 400 for fabricating a JFET device in accordance with embodiments of the present disclosure. In some embodiments, the steps of method 400 may be performed with fewer or more steps than shown in FIG. 4. For the sake of simplicity, additional fabrication steps such as the formation of the source, gate, and termination regions, as well as the back-side metallization to form drain contacts, are omitted from the steps of method 400. Moreover, in some embodiments, certain steps of method 400 may be omitted, repeated, performed in parallel, performed in a different order than shown in FIG. 4, or performed recursively. As one example, step 410 may be omitted in some embodiments.

Step 402 may include forming a spacer having a first spacer width on a surface of a semiconductor substrate. For example, as described above with reference to FIGS. 2B-2D, spacer 206 having a first spacer width 207 may be formed with spacer material 204 on the upper surface of the semiconductor substrate. In some embodiments, forming spacer 206 above the surface of the semiconductor substrate may include forming a patterned mask 202 over the semiconductor substrate, depositing spacer material 204 over patterned mask 202 and the semiconductor substrate, performing an isotropic etch targeting spacer material 204, and removing the patterned mask 202.

Step 404 may include using the first spacer width of the spacer as a first mask to form a gate region on opposing sides of a channel region extending vertically from a source region to a drift region. For example, as described above with reference to FIG. 2E, gate region 22 may be formed by doping portions of the semiconductor substrate with an opposite conductivity type relative to drift region 41, channel region 40, and source region 31. As shown in FIG. 2E, the formation of gate region 22 may be masked by spacer 206, and in particular the first spacer width 207 of spacer 206, to define a boundary of channel region 40, whereby channel region 40 extends vertically from source region 31 toward drift region 41.

Step 406 may include widening the spacer to a second spacer width greater than the first spacer width. In some embodiments, widening the spacer to a second spacer width greater than the first spacer width may include depositing a second spacer layer over the spacer material and the semiconductor substrate, and performing an isotropic etch targeting the second spacer layer. For example, as described above with reference to FIGS. 2F and 2G, the spacer width of spacer 206 may be increased or widened from a first spacer width 207 to a second spacer width 217 that is greater than the first spacer width 207. As shown in FIG. 2F, a second spacer layer 210 may be conformally deposited over spacer material 204 and the semiconductor substrate. Then, as shown in FIG. 2G, an isotropic etch may be applied to remove portions of second spacer layer 210. The isotropic etch of second spacer layer 210 may leave a portion of second spacer layer 210 on the sidewalls of spacer material 204, thereby increasing the spacer width of spacer 206 from a first spacer width 207 (shown in FIGS. 2D and 2E) to a second spacer width 217 (shown in FIG. 2G).

Step 408 may include using the second spacer width of the spacer as a second mask for forming a trench extending through the source region and into the gate region. For example, as described above with reference to FIG. 2H, a trench may be formed by etching through source region 31 and to gate region 22 using spacer 206 (the second spacer width 217 of spacer 206) as a mask. In some embodiments, etching through source region 31 to gate region 22 using spacer 206 as a mask may create a mesa within which remaining portions of source region 31 are disposed.

Step 410 may include further widening the spacer to a third spacer width greater than the second spacer width prior to forming the gate contact region. In some embodiments, further widening the spacer to a third spacer width greater than the second spacer width may include depositing an additional spacer layer over the spacer and the semiconductor substrate, and performing an isotropic etch targeting the additional spacer layer. For example, as described above with reference to FIGS. 2I and 2J, the spacer width of spacer 206 may be increased or widened from a second spacer width 217 to a third spacer width 227, which is greater than the second spacer width 217. As shown in FIG. 2I, an additional spacer layer 220 may be conformally deposited over spacer material 204, second spacer layer 210, and the semiconductor substrate. Subsequently, as shown in FIG. 2J, an isotropic etch may be applied to remove portions of additional spacer layer 220. The isotropic etch of additional spacer layer 220 may leave a portion of additional spacer layer 220 on the sidewalls of second spacer layer 210, thereby increasing the spacer width of spacer 206 from a second spacer width 217 (shown in FIGS. 2G and 2H) to a third spacer width 227 (shown in FIG. 2J).

As shown in FIG. 2K, the additional spacer layer 220 of spacer 206 may shield source region 31 from the doping used to form gate contact region 21. In some embodiments, the doping concentration (of the first conductivity type) of source region 31 may be significantly higher than the doping concentration (of the second conductivity type) used to form gate contact region 21. In such embodiments, the higher doping concentration of the first conductivity type for source region 31 may predominate even when exposed to the doping of the second conductivity type for gate contact region 21. Thus, in such embodiments, the addition of additional spacer layer 220 by the processing steps illustrated by FIGS. 2I and 2J may optionally be omitted. For such embodiments, method 400 may optionally omit step 410 and may proceed directly from step 408 to step 412.

Step 412 may include forming a gate contact region in the gate region. For example, as described above with reference to FIG. 2K, gate contact region 21 may be formed in gate region 22 using spacer 206 as a mask. Gate contact region 21 may be formed by doping portions of the gate region 22 with a higher doping concentration of the same conductivity type as gate region 22. In some embodiments, the higher doping concentration of gate contact region 21 may help facilitate the formation in later processing steps of a low-resistance gate contact 20 coupled to gate contact region 21.

Step 414 may include removing the spacer. For example, as described above with reference to FIG. 2L, an etch targeting spacer material 204, second spacer layer 210, and/or additional spacer layer 220 may be applied to remove spacer 206 from the upper surface of the semiconductor substrate.

Step 416 may include forming dielectric spacers on sidewalls of the source region. For example, as described above with reference to FIGS. 2M and 2N, dielectric spacers 60 may be formed on the sidewalls of source region 31. As shown in FIG. 2M, a dielectric layer 230 may be conformally deposited over the semiconductor substrate, including over gate contact region 21, gate region 22, and the mesa in which source region 31 is disposed. Subsequently, as shown in FIG. 2N, an isotropic etch may be applied to remove the upper and lower portions of dielectric layer 230 extending horizontally and parallel to the surface of the semiconductor substrate. The isotropic etch of dielectric layer 230 may leave vertically oriented portions of dielectric layer 230 to form dielectric spacers 60 on the sidewalls of source region 31.

Step 418 may include depositing a metal layer. For example, as described above with reference to FIG. 2O, a metal layer 240 may be conformally deposited on over the semiconductor substrate, including over source region 31, dielectric spacers 60, and gate contact region 21. Metal layer 240 may be formed with any suitable metal or metal alloy, such as nickel (N) or an alloy thereof.

Step 420 may include performing an anneal to cause portions of the metal layer to react with underlying areas of the source region and the gate contact region. For example, as also described above with reference to FIG. 2O, a low-temperature rapid thermal anneal (RTA) may be performed to cause portions of metal layer 240 to react with underlying areas of source region 31 and gate contact region 21. The reaction of metal with underlying semiconductor regions may form areas of silicide, for example a nickel silicide.

Step 422 may include removing non-reacted portions of the metal layer above the dielectric spacer. For example, as described above with reference to FIG. 2P, the non-reacted portions of metal layer 240, including the non-reacted portions of metal layer 240 above dielectric spacers 60, may be removed. The reacted portions of metal layer 240 may remain. For example, as shown in FIG. 2P, gate contact 20 and source contact 30 may be formed by the remaining areas of silicide (for example, nickel silicide) where metal layer 240 reacted with underlying areas of source region 31 and gate contact region 21.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

What is claimed is:

1. A method for fabricating a junction field-effect transistor (JFET) comprising:
forming a source region adjacent to a surface of a semiconductor substrate;
forming a spacer with a spacer material above the surface of the semiconductor substrate;
forming a gate region, wherein the gate region is masked by the spacer to define a boundary of a channel region extending vertically from the source region toward a drift region;
increasing a spacer width of the spacer;
etching through the source region and to the gate region using the spacer as a mask; and
forming a gate contact region in the gate region.

2. The method of claim 1, further comprising:
removing the spacer;
forming dielectric spacers on sidewalls of the source region;
depositing a metal layer;
performing an anneal to cause portions of the metal layer to react with underlying areas of the source region and the gate contact region; and
removing non-reacted portions of the metal layer above the dielectric spacers.

3. The method of claim 1, wherein forming the spacer above the surface of the semiconductor substrate comprises:
forming a patterned mask over the semiconductor substrate;
depositing the spacer material over the patterned mask and the semiconductor substrate;
performing an isotropic etch targeting the spacer material; and
removing the patterned mask.

4. The method of claim 1, wherein increasing the spacer width of the spacer includes:
depositing a second spacer layer over the spacer material and the semiconductor substrate; and
performing an isotropic etch targeting the second spacer layer.

5. The method of claim 1, further comprising further increasing the spacer width prior to forming the gate contact region.

6. The method claim 5, wherein further increasing the spacer width includes:
depositing an additional spacer layer over the spacer and the semiconductor substrate; and
performing an isotropic etch targeting the additional spacer layer.

7. The method of claim 1, wherein the channel region is formed with a channel width in a channel-width range of 0.2 μm to 1 μm.

8. The method of claim 1, wherein etching through the source region to the gate region using the spacer as the mask creates a mesa having a mesa-depth in a depth range of 0.1 μm to 0.3 μm and having a mesa-width in a width range of 0.5 μm to 1.0 μm.

9. The method of claim 1, wherein respective portions of the gate region are formed at a distance from each other to provide a cell pitch in a range of 1 μm to 2 μm.

10. The method of claim 1, wherein the semiconductor substrate is a silicon carbide (SiC) substrate.

11. The method of claim 1, wherein:
the source region, the channel region, and the drift region are n-type regions; and
the gate region and the gate contact region are p-type regions.

12. A method for fabricating a junction field-effect transistor (JFET) comprising:
forming a spacer having a first spacer width on a surface of a semiconductor substrate;
using the first spacer width of the spacer as a first mask to form a gate region on opposing sides of a channel region extending vertically from a source region to a drift region;
widening the spacer to a second spacer width greater than the first spacer width;
using the second spacer width of the spacer as a second mask for forming a trench extending through the source region and into the gate region; and
forming a gate contact region in the gate region.

13. The method of claim 12, further comprising:
removing the spacer;
forming dielectric spacers on sidewalls of the source region;
depositing a metal layer;
performing an anneal to cause portions of the metal layer to react with underlying areas of the source region and the gate contact region; and
removing non-reacted portions of the metal layer above the dielectric spacers.

14. The method of claim 12, wherein widening the spacer to the second spacer width greater than the first spacer width comprises:
depositing a second spacer layer over the spacer and the semiconductor substrate; and
performing an isotropic etch targeting the second spacer layer.

15. The method of claim 12, further comprising further widening the spacer to a third spacer width greater than the second spacer width prior to forming the gate contact region, wherein the third spacer width of the spacer is used as a third mask for forming the gate contact region.

16. The method of claim 15, wherein further widening the spacer comprises:
depositing an additional spacer layer over the spacer and the semiconductor substrate; and
performing an isotropic etch targeting the additional spacer layer.

17. A junction field-effect transistor (JFET) comprising:
a source region disposed in a mesa between two dielectric spacers, the source region coupled to a source contact on a first surface of a semiconductor substrate;
a drift region coupled to a drain contact on a second surface of the semiconductor substrate opposing the first surface;
a channel region extending vertically between the source region and the drift region;
a gate region disposed on opposing sides of the channel region; and
a gate contact region disposed within the gate region and coupled to a gate contact; and
wherein the JFET has a cell pitch in a range of 1 μm to 2 μm.

18. The JFET of claim 17, wherein the channel region has a channel width in a channel-width range of 0.2 μm to 1 μm.

19. The JFET of claim 17, wherein the mesa has a mesa-width in a width range of 0.5 μm to 1.0 μm and has a mesa-depth in a depth range of 0.1 μm to 0.3 μm.

20. The JFET of claim 17, wherein the JFET is a silicon carbide JFET.
